(19) United States
(12) Patent Application Publication
(10) Pub. No.: US 2025/0098360 A1
(43) Pub. Date: Mar. 20, 2025

(54) PHOTODIODE

(71) Applicant: ROHM CO., LTD., Kyoto (JP)

(72) Inventors: Toshikazu MUKAI, Kyoto (JP); Yoichi MUGINO, Kyoto (JP)

(73) Assignee: ROHM CO., LTD., Kyoto (JP)

(21) Appl. No.: 18/798,266

(22) Filed: Aug. 8, 2024

(30) Foreign Application Priority Data
Sep. 19, 2023 (JP) 2023-150959

(51) Int. Cl. H01L 31/0304; H01L 31/109

(52) U.S. Cl. CPC H10F 77/1248; H10F 30/222

(57) ABSTRACT

A photodiode comprises a substrate and a semiconductor stack. The substrate has a major surface. The semiconductor stack is disposed on the major surface. The semiconductor stack includes a buffer layer disposed on the major surface and a light absorption layer disposed on the buffer layer. The light absorption layer is formed of InₓGa₁₋ₓAs_{y}P_{1-y}, where x and y are larger than 0 and smaller than 1. The buffer layer is formed of In_{z}Ga_{1-z}As, where z is larger than 0 and smaller than 1.

### CROSS REFERENCE TO RELATED APPLICATIONS

This nonprovisional application is based on Japanese Patent Application No. 2023-150959 filed on Sep. 19, 2023 with the Japan Patent Office, the entire contents of which are hereby incorporated by reference.

### BACKGROUND OF THE INVENTION

### Field of the Invention

The present disclosure relates to a photodiode.

### Description of the Background Art

Japanese Patent Laying-Open No. 11-054785 discloses a light receiving device.

### BRIEF DESCRIPTION OF THE DRAWINGS

FIG. 1 is a schematic cross section of a photodiode according to an embodiment.

FIG. 2 is a schematic partial plan view of the photodiode of the embodiment as seen in a direction indicated by an arrow II shown in FIG. 1.

FIG. 3 represents a relationship between InGaAsP's lattice constant and bandgap energy.

FIG. 4 is a schematic cross section showing one step of a method for manufacturing a photodiode according to an embodiment.

FIG. 5 is a schematic cross section showing a step following the step shown in FIG. 4 in the method for manufacturing the photodiode according to the embodiment.

FIG. 6 is a schematic cross section showing a step following the step shown in FIG. 5 in the method for manufacturing the photodiode according to the embodiment.

FIG. 7 is a schematic cross section showing a step following the step shown in FIG. 6 in the method for manufacturing the photodiode according to the embodiment.

FIG. 8 is a schematic cross section showing a step following the step shown in FIG. 7 in the method for manufacturing the photodiode according to the embodiment.

FIG. 9 is a schematic cross section showing a step following the step shown in FIG. 8 in the method for manufacturing the photodiode according to the embodiment.

FIG. 10 is a schematic cross section showing a step following the step shown in FIG. 9 in the method for manufacturing the photodiode according to the embodiment.

FIG. 11 is a schematic cross section showing a step following the step shown in FIG. 10 in the method for manufacturing the photodiode according to the embodiment.

FIG. 12 is a diagram showing a result of a simulation of a relationship between a bias voltage applied to a photodiode and a dark current of the photodiode.

FIG. 13 is a diagram showing a result of a simulation of a relationship between a compositional ratio of arsenic in a light absorption layer and a dark current of a photodiode for a bias voltage of −1 V.

FIG. 14 is a SEM image of a cross section of a portion of a photodiode of a first example.

FIG. 15 is a SEM image of a cross section of a portion of a photodiode of a first comparative example.

FIG. 16 is a diagram showing an exemplary experiment for a relationship between bias voltage and a dark current of the photodiode of the example and a dark current of the photodiode of the comparative example.

FIG. 17 is a diagram showing a result of a simulation of a relationship between a distance between an edge of an opening of an insulating layer that defines a p-type diffusion region and a side surface of a mesa structure, and a dark current of a photodiode for a bias voltage of −1 V.

### DETAILED DESCRIPTION

An embodiment of the present disclosure will now be specifically described with reference to the drawings. In the following figures, identical or equivalent components are identically denoted and will not be described repeatedly. At least a part in configuration of the embodiment described below may be combined as desired.

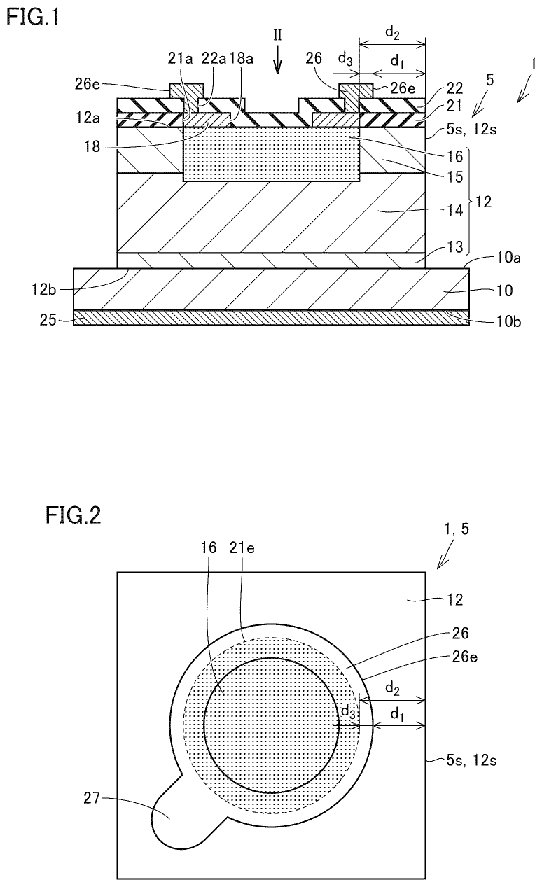

A photodiode 1 according to an embodiment of the present disclosure will now be described with reference to FIGS. 1 and 2. Photodiode 1 comprises a substrate 10, a semiconductor stack 12, a p-type contact layer 18, an insulating layer 21, an antireflection film 22, an n-electrode 25, a p-electrode 26, and a conductive pad 27.

Substrate 10 has a major surface 10a and a major surface 10b opposite to major surface 10a. Major surface 10a and major surface 10b are end surfaces opposite in the direction of the thickness of substrate 10. Substrate 10 is for example a semiconductor substrate such as an InP substrate.

Semiconductor stack 12 is disposed on substrate 10 at major surface 10a. Semiconductor stack 12 has a top surface 12a and a bottom surface 12b. Bottom surface 12b is in contact with major surface 10a. A side surface 12s is connected to top surface 12a and bottom surface 12b. Semiconductor stack 12 includes a buffer layer 13, a light absorption layer 14, and a p-type dopant diffusion region 16. Semiconductor stack 12 may further include a window layer 15. Semiconductor stack 12 includes a plurality of stacked semiconductor layers. For example, semiconductor stack 12 has buffer layer 13, light absorption layer 14, and window layer 15 stacked together.

Buffer layer 13 is disposed on substrate 10 at major surface 10a. Buffer layer 13 is in contact with substrate 10. Buffer layer 13 has a bottom surface, which is bottom surface 12b of semiconductor stack 12. Buffer layer 13 is for example an i-type semiconductor layer. Buffer layer 13 has a thickness for example of 10 nm or larger. Buffer layer 13 may have a thickness of 100 nm or larger. Buffer layer 13 can thus reduce crystal defects in light absorption layer 14 and also allows light absorption layer 14 to have a flatter top surface. Buffer layer 13 is smaller in thickness than light absorption layer 14. Buffer layer 13 has a thickness for example of 1000 nm or smaller. Buffer layer 13 may have a thickness of 800 nm or smaller, 600 nm or smaller, 400 nm or smaller, or 200 nm or smaller. This can reduce voltage drop in buffer layer 13 and allows increased reverse bias voltage to be applied to light absorption layer 14.

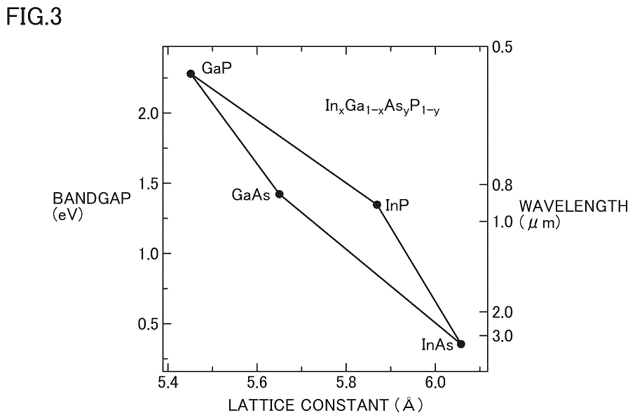

Buffer layer 13 is formed of In_{z}Ga_{1-z}As, where z is larger than 0 and smaller than 1. Buffer layer 13 is lattice-matched to substrate 10 (e.g., an InP substrate). As shown in FIG. 3, adjusting z allows buffer layer 13 to be lattice-matched to the InP substrate. In the present specification, buffer layer 13 being lattice-matched to substrate 10 means that a difference between the lattice constant of buffer layer 13 and the lattice constant of substrate 10 is equal to or smaller than 0.1% of the lattice constant of substrate 10.

Light absorption layer 14 is disposed on buffer layer 13. Light absorption layer 14 is in contact with buffer layer 13. Light absorption layer 14 is isolated from substrate 10 by buffer layer 13. Light absorption layer 14 is for example an i-type semiconductor layer. Light absorption layer 14 absorbs light entering photodiode 1. Photodiode 1 detects the intensity of the light.

Light absorption layer 14 is formed of InₓGa₁₋ₓAs_{y}P_{1-y}, where x and y are larger than 0 and smaller than 1. x is for example 0.70 or larger and smaller than 1.00. x is determined depending on the wavelength of the light detected by photodiode 1, that is, the wavelength of the light absorbed by light absorption layer 14. Photodiode 1 detects light having a wavelength for example of 1690 nm or smaller. Light absorption layer 14 has a thickness for example of 3000 nm or larger and 5000 nm or smaller. Light absorption layer 14 is lattice-matched to substrate 10 (e.g., an InP substrate). As shown in FIG. 3, adjusting x and y allows light absorption layer 14 to be lattice-matched to the InP substrate while changing the bandgap energy of light absorption layer 14. In the present specification, light absorption layer 14 being lattice-matched to substrate 10 means that a difference between the lattice constant of light absorption layer 14 and the lattice constant of substrate 10 is equal to or smaller than 0.1% of the lattice constant of substrate 10.

Window layer 15 is disposed on light absorption layer 14. Window layer 15 may for example be an n-type semiconductor layer. Window layer 15 has a thickness for example of 100 nm or larger and 2000 nm or smaller. Window layer 15 has a top surface, which may be top surface 12a of semiconductor stack 12. Window layer 15 has a bandgap energy larger than that of light absorption layer 14. Window layer 15 is transparent to the light detected by photodiode 1. Window layer 15 has a bandgap wavelength shorter than the wavelength of light detected by photodiode 1. Window layer 15 is for example an n-InP layer.

P-type dopant diffusion region 16 is a region having a p-type dopant such as zinc (Zn) diffused therein, and is a p-type semiconductor region. P-type dopant diffusion region 16 extends from top surface 12a of semiconductor stack 12 into light absorption layer 14. In the present embodiment, light absorption layer 14 and window layer 15 are doped with a p-type dopant to form p-type dopant diffusion region 16. P-type dopant diffusion region 16 is in contact with light absorption layer 14 and window layer 15. P-type dopant diffusion region 16 is spaced from bottom surface 12b of semiconductor stack 12.

Semiconductor stack 12 has a mesa structure 5. Side surface 12s of semiconductor stack 12 is a side surface 5s of mesa structure 5. In the present embodiment, window layer 15, light absorption layer 14, and buffer layer 13 are formed in mesa structure 5. At least a portion of side surface 12s of semiconductor stack 12 may be side surface 5s of mesa structure 5. For example, while buffer layer 13 may not be formed in mesa structure 5, window layer 15 and light absorption layer 14 may be formed in mesa structure 5.

P-type contact layer 18 is disposed on semiconductor stack 12 at top surface 12a. P-type contact layer 18 is in contact with p-type dopant diffusion region 16. P-type contact layer 18 is disposed in an opening 21a of insulating layer 21. P-type contact layer 18 is in contact with insulating layer 21. P-type contact layer 18 has a thickness for example of 10 nm or larger and 200 nm or smaller. P-type contact layer 18 is for example a p-InGaAs layer. P-type contact layer 18 is provided with an opening 18a. P-type dopant diffusion region 16 is exposed from p-type contact layer 18 through opening 18a. Light detected by photodiode 1 passes through opening 18a and enters light absorption layer 14.

Insulating layer 21 is disposed on semiconductor stack 12. Insulating layer 21 is in contact with top surface 12a of semiconductor stack 12. Insulating layer 21 has a thickness for example of 10 nm or larger and 500 nm or smaller. Insulating layer 21 is for example a silicon nitride layer. Insulating layer 21 is provided with opening 21a. In a plan view of major surface 10a, opening 21a defines p-type dopant diffusion region 16. Insulating layer 21 functions as a mask that defines a p-type dopant implantation region for p-type dopant diffusion region 16. In a plan view of major surface 10a, a minimum distance d₂ between an edge of opening 21a and side surface 5s of mesa structure 5 is 20 μm or larger. Minimum distance d₂ may be 30 μm or larger, 40 μm or larger, or 50 μm or larger.

Antireflection film 22 reduces reflectance of light on an incident surface of photodiode 1. Antireflection film 22 is disposed on insulating layer 21, p-type contact layer 18, and semiconductor stack 12 (more specifically, p-type dopant diffusion region 16). Antireflection film 22 is for example an insulating layer. Antireflection film 22 is for example a silicon nitride layer. Antireflection film 22 is provided with a through hole 22a. P-type contact layer 18 is exposed from antireflection film 22 in through hole 22a.

N-electrode 25 is disposed on substrate 10 at major surface 10b. P-electrode 26 is disposed on antireflection film 22, in through hole 22a, and on p-type contact layer 18 exposed in through hole 22a. P-electrode 26 is in contact with p-type contact layer 18. P-electrode 26 is in electrical conduction with p-type dopant diffusion region 16 through p-type contact layer 18. In a plan view of major surface 10a, p-electrode 26 has an outer edge 26e. Conductive pad 27 is disposed on antireflection film 22 and connected to p-electrode 26. N-electrode 25, p-electrode 26, and conductive pad 27 are, for example, a stack of a titanium (Ti) layer, a platinum (Pt) layer and a gold (Au) layer, and the gold layer is an outermost surface layer of the stack.

In a plan view of major surface 10a, a minimum distance d₁ between outer edge 26e of p-electrode 26 and side surface 5s of mesa structure 5 is 18 μm or larger. Minimum distance d₁ may be 28 μm or larger, 38 μm or larger, or 48 μm or larger. Minimum distance d₁ between outer edge 26e of p-electrode 26 and side surface 5s of mesa structure 5 may be smaller than minimum distance d₂ between the edge of opening 21a of insulating layer 21 and side surface 5s of mesa structure 5. In a plan view of major surface 10a, a maximum distance d₃ between outer edge 26e of p-electrode 26 and the edge of opening 21a of insulating layer 21 is 2 μm or smaller.

How photodiode 1 of the present embodiment operates will now be described. A reverse bias voltage is applied between p-electrode 26 and n-electrode 25. That is, a bias voltage is applied between p-electrode 26 and n-electrode 25 so that n-electrode 25 is higher in potential than p-electrode 26. Light passes through opening 18a and enters light absorption layer 14. In light absorption layer 14, electrons and holes are generated. By the reverse bias voltage, the electrons are moved to p-electrode 26 and the holes are moved to n-electrode 25. A photocurrent depending on intensity of light entering photodiode 1 is generated. The intensity of the light entering photodiode 1 is detected from the photocurrent generated in photodiode 1.

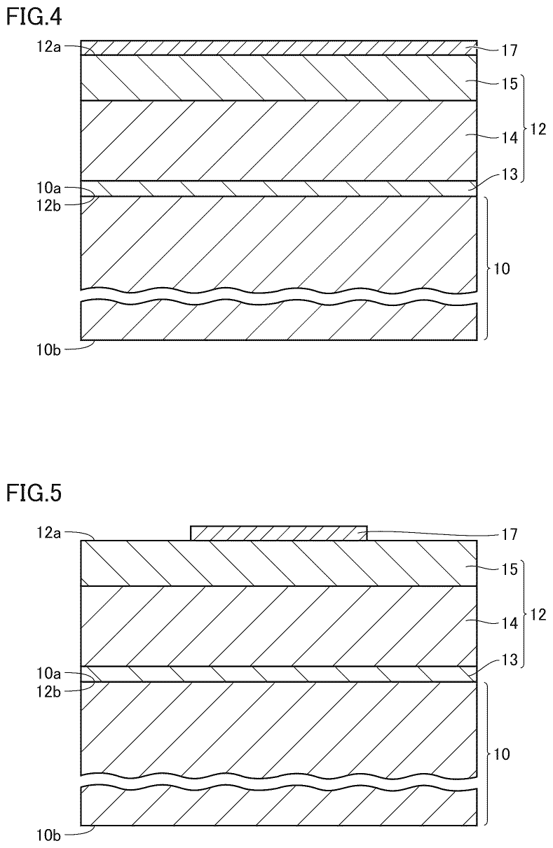

An example of a method for manufacturing photodiode 1 according to the present embodiment will now be described with reference to FIGS. 4 to 11.

Referring to FIG. 4, buffer layer 13 is formed on substrate 10 at major surface 10a. For example, buffer layer 13 formed of In_{z}Ga_{1-z}As is formed on an InP substrate through metal organic chemical vapor deposition (MOCVD). Buffer layer 13 is lattice-matched to substrate 10 (e.g., an InP substrate).

Light absorption layer 14 is formed on buffer layer 13 for example through MOCVD. Light absorption layer 14 is formed of InₓGa₁₋ₓAs_{y}P_{1-y}, where x and y are larger than 0 and smaller than 1. x is for example 0.70 or larger and smaller than 1.00. Light absorption layer 14 is lattice-matched to substrate 10 (e.g., an InP substrate).

Window layer 15 is formed on light absorption layer 14 for example through MOCVD. Window layer 15 is for example an n-InP layer. Semiconductor stack 12 is thus formed on substrate 10 at major surface 10a. Semiconductor stack 12 has top surface 12a and bottom surface 12b.

Referring to FIG. 4, a semiconductor layer 17 is formed on semiconductor stack 12 at top surface 12a (or on window layer 15) for example through MOCVD. Semiconductor layer 17 is formed on top surface 12a (or window layer 15) in a region overlapping p-type dopant diffusion region 16 in a plan view of major surface 10a (see FIGS. 1 and 2). Semiconductor layer 17 is formed for example of InGaAs.

Referring to FIG. 5, semiconductor layer 17 is etched for example by dry etching such as reactive ion etching (RIE). In a plan view of major surface 10a, a portion of top surface 12a of semiconductor stack 12 or a portion of window layer 15 is exposed from semiconductor layer 17.

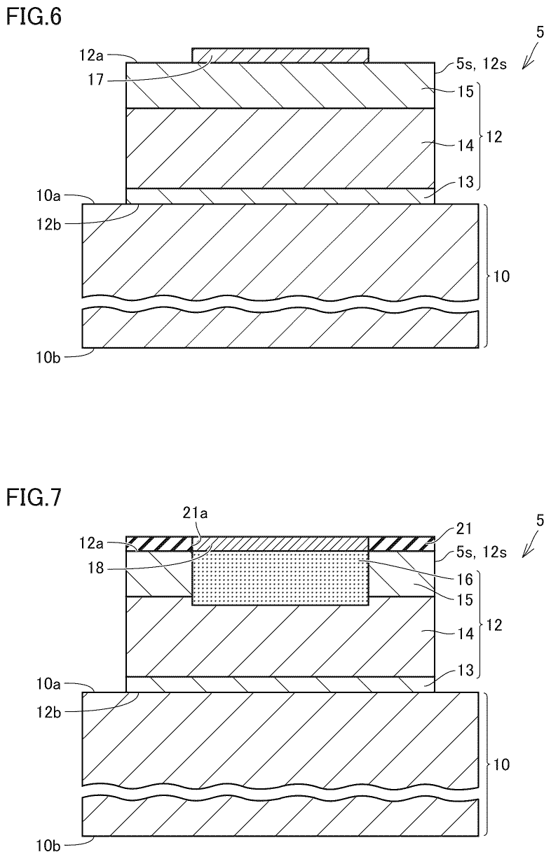

Referring to FIG. 6, semiconductor stack 12 is formed into mesa structure 5 (S8). Specifically, buffer layer 13, light absorption layer 14, and window layer 15 are etched by dry etching. The layers are dry-etched for example by RIE using an etching gas such as a chlorine-based gas. Since mesa structure 5 is formed by dry etching rather than wet etching, mesa structure 5 is prevented from having side surface 5s excessively etched away. This can prevent a distance between side surface 5s of mesa structure 5 and p-type dopant diffusion region 16 (see FIGS. 1 and 2) and a distance between side surface 5s of mesa structure 5 and outer edge 26e of p-electrode 26 (see FIGS. 1 and 2) from having an excessive reduction in a plan view of major surface 10a.

Referring to FIG. 7, a p-type dopant is introduced into semiconductor stack 12 and semiconductor layer 17 to form p-type dopant diffusion region 16 and p-type contact layer 18. Specifically, insulating layer 21 is formed on a portion of top surface 12a of semiconductor stack 12 or window layer 15 that is exposed from semiconductor layer 17 for example through plasma CVD. Semiconductor layer 17 is disposed in opening 21a of insulating layer 21. Subsequently, a p-type dopant such as zinc (Zn) is introduced into semiconductor layer 17, window layer 15, and light absorption layer 14 with insulating layer 21 used as a mask. The p-type dopant is introduced through opening 21a of insulating layer 21 to dope semiconductor layer 17, window layer 15, and light absorption layer 14. Semiconductor layer 17 doped with the p-type dopant forms p-type contact layer 18. Window layer 15 and light absorption layer 14 doped with the p-type dopant form p-type dopant diffusion region 16.

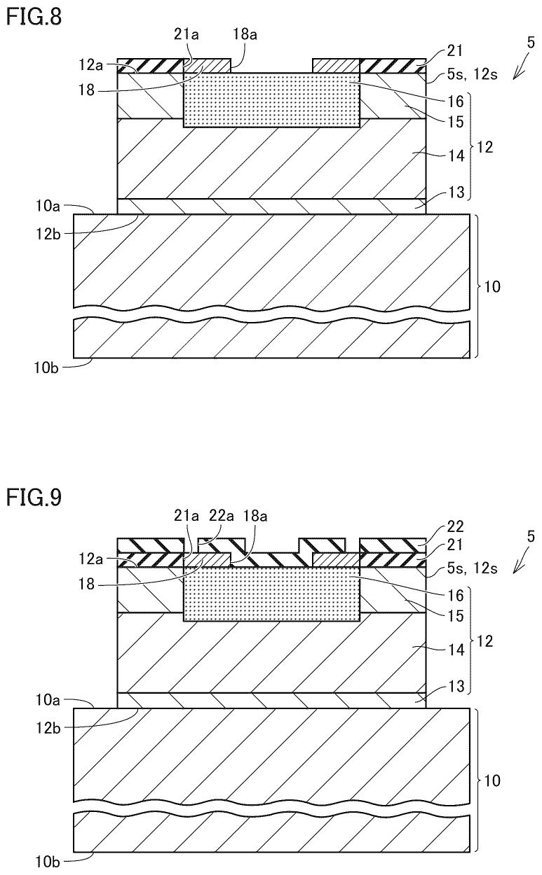

Referring to FIG. 8, opening 18a is formed in p-type contact layer 18. For example, opening 18a is formed in p-type contact layer 18 by RIE using an etching gas such as a chlorine-based gas. A portion of p-type dopant diffusion region 16 is exposed from p-type contact layer 18 through opening 18a.

Referring to FIG. 9, antireflection film 22 provided with through hole 22a is formed on insulating layer 21, p-type contact layer 18, and p-type dopant diffusion region 16. For example, antireflection film 22 is formed through plasma CVD. Through hole 22a is formed through antireflection film 22 by etching a portion of antireflection film 22 by dry etching such as RIE using an etching gas such as carbon tetrafluoride (CF₄) gas. A portion of p-type contact layer 18 is exposed from antireflection film 22 through hole 22a.

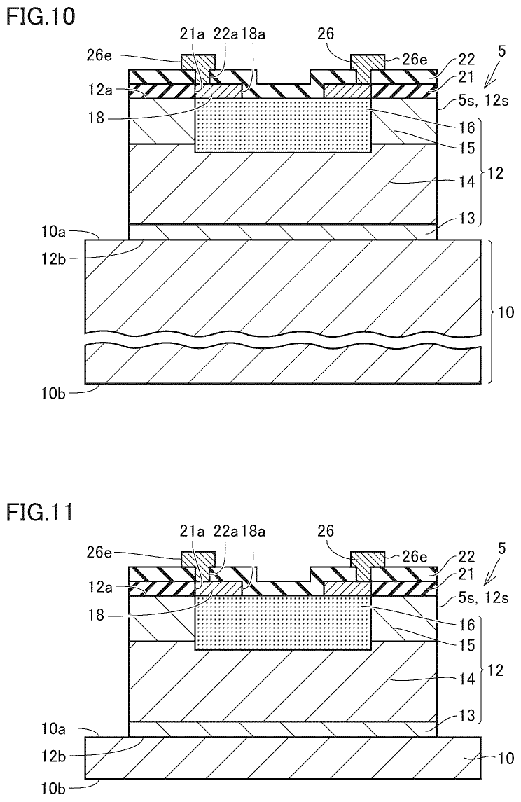

Referring to FIG. 10, p-electrode 26 and conductive pad 27 (see FIG. 2) are formed. For example, p-electrode 26 and conductive pad 27 are formed by vapor deposition of a titanium (Ti) layer, a platinum (Pt) layer and a gold (Au) layer in this order. P-electrode 26 is formed on antireflection film 22, in through hole 22a, and on p-type contact layer 18 exposed through hole 22a. Conductive pad 27 is formed on antireflection film 22 and also connected to p-electrode 26.

Referring to FIG. 11, substrate 10 is ground at major surface 10b and thus reduced in thickness. Subsequently, n-electrode 25 is formed on substrate 10 at major surface 10b. For example, n-electrode 25 is formed by vapor deposition of a titanium (Ti) layer, a platinum (Pt) layer and a gold (Au) layer in this order. Photodiode 1 shown in FIGS. 1 and 2 is thus obtained.

A function of photodiode 1 of the present embodiment will now be described. Photodiode 1 has a dark current reduced for the following three reasons.

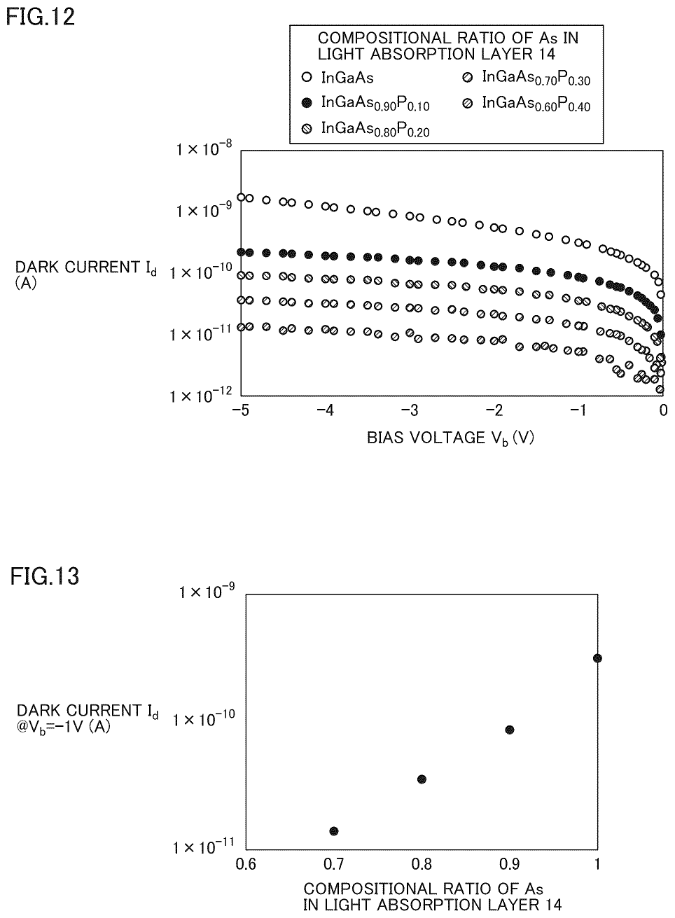

First, light absorption layer 14 is formed of InGaAsP rather than InGaAs. As shown in FIG. 3, when InGaAsP has an increased compositional ratio of As, InGaAsP has increased bandgap energy. InGaAsP has a bandgap energy larger than that of InGaAs. As light absorption layer 14 has increasing bandgap energy, a current due to minority carriers diffused in a depletion layer created when a reverse bias voltage (or a negative bias voltage V_{b}) is applied and a current due to a trap level in that depletion layer decrease. Dark current I_{d} of light absorption layer 14 decreases. Therefore, as shown in FIGS. 12 and 13, as light absorption layer 14 has increasing bandgap energy, photodiode 1 has decreasing dark current Ia. Note that light absorption layer 14 indicated in FIGS. 12 and 13 is lattice-matched to substrate 10 that is an InP substrate.

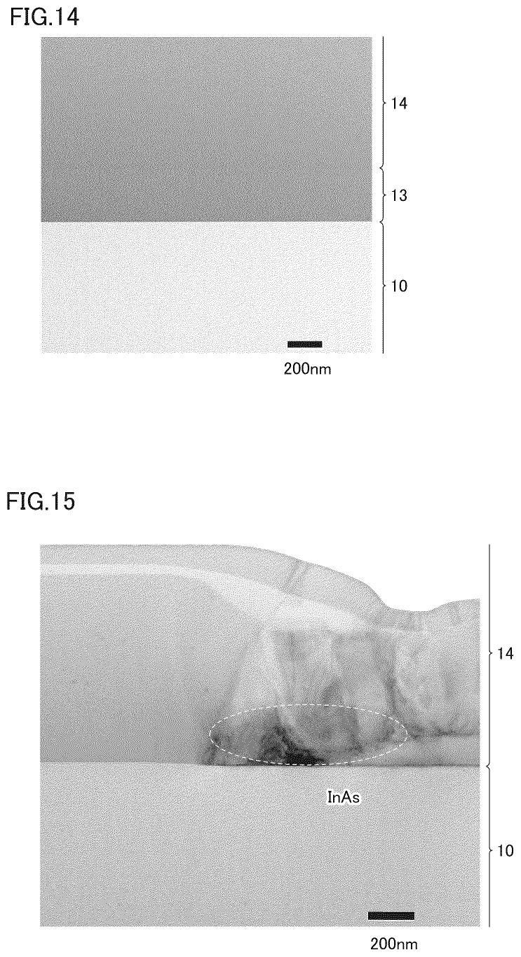

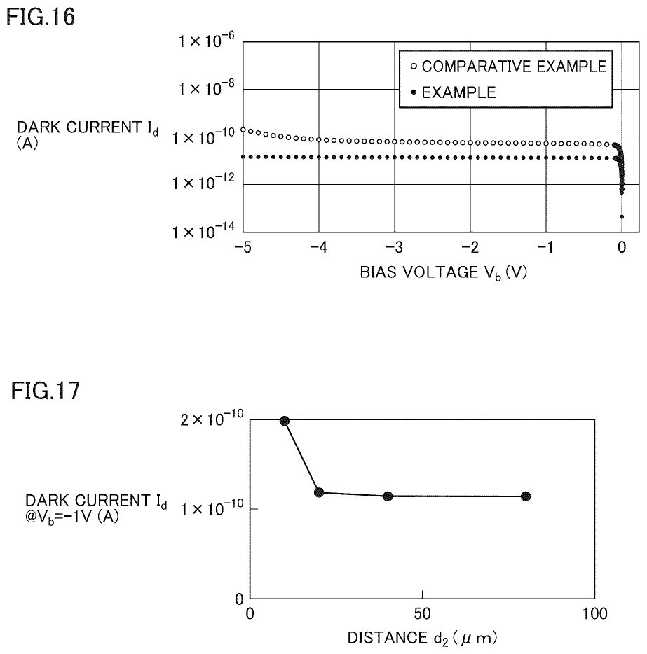

Second, light absorption layer 14 formed of InGaAsP is formed on buffer layer 13 formed of InGaAs. Therefore, as shown in FIG. 14, light absorption layer 14 has reduced crystal defects therein and also has a flat top surface. In contrast, as shown in FIG. 15, in a comparative example in which light absorption layer 14 formed of InGaAsP is formed directly on an InP substrate, light absorption layer 14 has crystal defects increased as an InAs region lattice-mismatched with the InP substrate is formed in light absorption layer 14. In addition, in the comparative example, light absorption layer 14 has a rough top surface. The crystal defects and surface roughness of light absorption layer 14 increase dark current I_{d} of the photodiode. Accordingly, as shown in FIG. 16, light absorption layer 14 formed of InGaAsP is formed on buffer layer 13 formed of InGaAs to reduce dark current I_{d} of photodiode 1. Referring to FIG. 16, photodiode 1 of an example that is one example of the present embodiment has dark current I_{d} reduced to one third of dark current I_{d} of the photodiode of the comparative example.

Third, in a plan view of major surface 10a, minimum distance d₁ between outer edge 26e of p-electrode 26 and side surface 5s of mesa structure 5 is 18 μm or larger. Therefore, a distance between outer edge 26e of p-electrode 26 and side surface 5s of mesa structure 5 increases. When a reverse bias voltage (or negative bias voltage V_{b}) is applied to photodiode 1, an electric field concentrates at outer edge 26e of p-electrode 26, and outer edge 26e of p-electrode 26 becomes a region of a strong electric field in photodiode 1, however, the region of the strong electric field in photodiode 1 is prevented from reaching side surface 5s of mesa structure 5. Thus, dark current I_{d} of photodiode 1 is reduced.

In a plan view of major surface 10a, minimum distance d₂ between the edge of opening 21a of insulating layer 21 and side surface 5s of mesa structure 5 is 20 μm or larger. Therefore, a distance between p-type dopant diffusion region 16 defined by opening 21a of insulating layer 21 and side surface 5s of mesa structure 5 increases. When a reverse bias voltage (or negative bias voltage V_{b}) is applied to photodiode 1, p-type dopant diffusion region 16 becomes a region of a strong electric field in photodiode 1, however, the region of the strong electric field in photodiode 1 is prevented from reaching side surface 5s of mesa structure 5. Thus, as shown in FIG. 17, dark current I_{d} of photodiode 1 is reduced. In contrast, when minimum distance d₂ between the edge of opening 21a of insulating layer 21 and side surface 5s of mesa structure 5 is 10 μm, the region of the strong electric field in photodiode 1 reaches side surface 5s of mesa structure 5, and, as shown in FIG. 17, dark current I_{d} of photodiode 1 increases.

In a plan view of major surface 10a, maximum distance d₃ between outer edge 26e of p-electrode 26 and the edge of opening 21a of insulating layer 21 is 2 μm or smaller. Therefore, a distance between outer edge 26e of p-electrode 26 and side surface 5s of mesa structure 5 and a distance between p-type dopant diffusion region 16 and side surface 5s of mesa structure 5 increase. When a reverse bias voltage (or negative bias voltage V_{b}) is applied to photodiode 1, a region of a strong electric field in photodiode 1 is prevented from reaching side surface 5s of mesa structure 5. Thus, dark current I_{d} of photodiode 1 is reduced.

Photodiode 1 of the present embodiment has an effect, as described below.

Photodiode 1 of the present embodiment comprises substrate 10 and semiconductor stack 12. Substrate 10 has major surface 10a. Semiconductor stack 12 is disposed on substrate 10 at major surface 10a. Semiconductor stack 12 includes buffer layer 13 disposed on substrate 10 at major surface 10a, and light absorption layer 14 disposed on buffer layer 13. Light absorption layer 14 is formed of InₓGa₁₋ₓAs_{y}P_{1-y}, where x and y are larger than 0 and smaller than 1. Buffer layer 13 is formed of In_{z}Ga_{1-z}As, where z is larger than 0 and smaller than 1.

Light absorption layer 14 is formed of InGaAsP rather than InGaAs. And InGaAsP has a bandgap energy larger than that of InGaAs. Further, light absorption layer 14 formed of InGaAsP is formed on buffer layer 13 formed of InGaAs, and light absorption layer 14 has reduced crystal defects therein and also has a flat top surface. Photodiode 1 thus has a reduced dark current.

In photodiode 1 of the present embodiment, substrate 10 is an InP substrate. Light absorption layer 14 and buffer layer 13 are lattice-matched to the InP substrate.

Therefore, light absorption layer 14 and buffer layer 13 have reduced crystal defects therein. Photodiode 1 has a reduced dark current.

In photodiode 1 of the present embodiment, y is 0.70 or larger and smaller than 1.00.

Therefore, photodiode 1 can be used to detect intensity of light in a wavelength range of 1400 nm to 1690 nm with high accuracy.

Photodiode 1 of the present embodiment further comprises p-electrode 26. Semiconductor stack 12 further includes p-type dopant diffusion region 16 and has mesa structure 5. P-type dopant diffusion region 16 is in contact with light absorption layer 14 and in electrical conduction with p-electrode 26. In a plan view of major surface 10a of substrate 10, minimum distance d₁ between outer edge 26e of p-electrode 26 and side surface 5s of mesa structure 5 is 18 μm or larger.

Therefore, a distance between outer edge 26e of p-electrode 26 and side surface 5s of mesa structure 5 increases. When a reverse bias voltage is applied to photodiode 1, an electric field concentrates at outer edge 26e of p-electrode 26, and outer edge 26e of p-electrode 26 becomes a region of a strong electric field in photodiode 1, however, the region of the strong electric field in photodiode 1 is prevented from reaching side surface 5s of mesa structure 5. Photodiode 1 has a reduced dark current.

Photodiode 1 of the present embodiment further comprises insulating layer 21 disposed on semiconductor stack 12. Insulating layer 21 is provided with opening 21a. In a plan view of major surface 10a of substrate 10, opening 21a of insulating layer 21 defines p-type dopant diffusion region 16. In a plan view of major surface 10a, minimum distance d₂ between the edge of opening 21a of insulating layer 21 and side surface 5s of mesa structure 5 is 20 μm or larger.

Therefore, a distance between p-type dopant diffusion region 16 and side surface 5s of mesa structure 5 increases. When a reverse bias voltage is applied to photodiode 1, p-type dopant diffusion region 16 becomes a region of a strong electric field in photodiode 1, however, the region of the strong electric field in photodiode 1 is prevented from reaching side surface 5s of mesa structure 5. Photodiode 1 has a reduced dark current.

In photodiode 1 of the present embodiment, in a plan view of major surface 10a of substrate 10, maximum distance d₃ between outer edge 26e of p-electrode 26 and the edge of opening 21a of insulating layer 21 is 2 μm or smaller.

Therefore, a distance between outer edge 26e of p-electrode 26 and side surface 5s of mesa structure 5 and a distance between p-type dopant diffusion region 16 and side surface 5s of mesa structure 5 increase. When a reverse bias voltage is applied to photodiode 1, a region of a strong electric field in photodiode 1 is prevented from reaching side surface 5s of mesa structure 5. Photodiode 1 has a reduced dark current.

Hereinafter, aspects of the present disclosure will be collectively described as additional notes.

### (Additional Note 1)

A photodiode comprising:
a substrate having a major surface; and
a semiconductor stack disposed on the major surface,
the semiconductor stack including a buffer layer disposed on the major surface and a light absorption layer disposed on the buffer layer,
the light absorption layer being formed of InₓGa₁₋ₓAs_{y}P_{1-y}, where x and y are larger than 0 and smaller than 1,
the buffer layer being formed of In_{z}Ga_{1-z}As, where z is larger than 0 and smaller than 1.

### (Additional Note 2)

The photodiode according to Additional Note 1, wherein
the substrate is an InP substrate, and
the light absorption layer and the buffer layer are lattice-matched to the InP substrate.

### (Additional Note 3)

The photodiode according to Additional Note 1 or 2, wherein y is 0.70 or larger and smaller than 1.00.

### (Additional Note 4)

The photodiode according to any one of Additional Notes 1 to 3, further comprising a p-electrode, wherein
the semiconductor stack further includes a p-type dopant diffusion region and also has a mesa structure,
the p-type dopant diffusion region is in contact with the light absorption layer and in electrical conduction with the p-electrode, and
in a plan view of the major surface, a minimum distance between an outer edge of the p-electrode and a side surface of the mesa structure is 18 μm or larger.

### (Additional Note 5)

The photodiode according to Additional Note 4, further comprising an insulating layer disposed on the semiconductor stack, wherein
the insulating layer is provided with an opening,
in the plan view of the major surface, the opening defines the p-type dopant diffusion region, and
in the plan view of the major surface, a minimum distance between an edge of the opening and the side surface of the mesa structure is 20 μm or larger.

### (Additional Note 6)

The photodiode according to Additional Note 5, wherein in the plan view of the major surface a maximum distance between the outer edge of the p-electrode and the edge of the opening is 2 μm or smaller.

The presently disclosed embodiments should be considered as illustrative not restrictive in any respect. The scope of the present disclosure is defined by the terms of the claims, rather than the description above, and is intended to include any modifications within the meaning and scope equivalent to the terms of the claims.

What is claimed is:

1. A photodiode comprising:
a substrate having a major surface; and
a semiconductor stack disposed on the major surface,
the semiconductor stack including a buffer layer disposed on the major surface and a light absorption layer disposed on the buffer layer,
the light absorption layer being formed of InₓGa₁₋ₓAs_{y}P_{1-y}, where x and y are larger than 0 and smaller than 1,
the buffer layer being formed of In_{z}Ga_{1-z}As, where z is larger than 0 and smaller than 1.

2. The photodiode according to claim 1, wherein
the substrate is an InP substrate, and
the light absorption layer and the buffer layer are lattice-matched to the InP substrate.

3. The photodiode according to claim 1, wherein y is 0.70 or larger and smaller than 1.00.

4. The photodiode according to claim 1, further comprising a p-electrode, wherein
the semiconductor stack further includes a p-type dopant diffusion region and also has a mesa structure,
the p-type dopant diffusion region is in contact with the light absorption layer and in electrical conduction with the p-electrode, and
in a plan view of the major surface, a minimum distance between an outer edge of the p-electrode and a side surface of the mesa structure is 18 μm or larger.

5. The photodiode according to claim 4, further comprising an insulating layer disposed on the semiconductor stack, wherein
the insulating layer is provided with an opening,
in the plan view of the major surface, the opening defines the p-type dopant diffusion region, and
in the plan view of the major surface, a minimum distance between an edge of the opening and the side surface of the mesa structure is 20 μm or larger.

6. The photodiode according to claim 5, wherein in the plan view of the major surface a maximum distance between the outer edge of the p-electrode and the edge of the opening is 2 μm or smaller.
